(19) United States
(12) Patent Application Publication
(10) Pub. No.: US 2025/0253846 A1
(43) Pub. Date: Aug. 7, 2025

(54) GATE DRIVE DEVICE, AND GATE DRIVE SYSTEM

(71) Applicants: The University of Tokyo, Tokyo (JP); MITSUBISHI ELECTRIC CORPORATION, Tokyo (JP)

(72) Inventors: Makoto TAKAMIYA, Tokyo (JP); Katsuhiro HATA, Tokyo (JP); Kohei HORII, Tokyo (JP); Koji TANAKA, Tokyo (JP); Kiyoto WATABE, Tokyo (JP)

(21) Appl. No.: 18/854,392

(22) PCT Filed: Apr. 28, 2022
(86) PCT No.: PCT/JP2022/019327

§ 371 Date: Oct. 4, 2024

(51) Int. Cl. H03K 17/687; H03K 17/567

(52) U.S. Cl. CPC H03K 17/6877; H03K 17/567; H03K 17/6871; H03K 2217/0063; H03K 2217/0072

(57) ABSTRACT

A gate drive device operates on two sides, a high side and a low side, and drives a gate of a power transistor. The gate drive device includes: a control device provided in pair to constitute the two sides, and configured to output a switching signal of three or more levels including a high level, a low level, and one or more intermediate levels between the high level and the low level according to a received control signal; and a switching element provided in pair corresponding to the control device, and configured to output, to the gate of the power transistor, a voltage corresponding to a level of the switching signal received from the control device.

### TECHNICAL FIELD

The present invention relates to a gate drive device and a gate drive system.

### BACKGROUND ART

A power transistor such as an insulated gate bipolar transistor (IGBT) is subjected to switching control by changing a gate voltage by a gate driver (also referred to as a gate drive device). In recent years, in order to save power of a power transistor, a gate driver that changes a gate voltage using an improved control method has been developed.

JP 2017-135589 A discloses a gate driver for variably controlling a gate driver of a power transistor at a plurality of levels. According to this gate driver, a drive loss of the power transistor is reduced by controlling the power transistor by dynamically changing a gate voltage at a plurality of levels.

### SUMMARY OF INVENTION

A power transistor includes a capacitance between each terminal, and the capacitance needs to be charged and discharged to drive a gate. In recent years, efforts have been made to increase power of the power transistor, and a current input to the gate to charge the capacitance is required to be relatively large, for example, 40 A or more. In order to increase an output current in the gate driver having the configuration disclosed in JP 2017-135589 A, it is necessary to provide more transistors in parallel, which poses a problem of increasing an area occupied by the gate driver.

The invention has been made to solve such a problem, and an object thereof is to provide a gate drive device and a gate drive system capable of variably controlling an output at a plurality of levels with a simpler configuration.

A gate drive device according to an aspect of the invention operates on two sides, a high side and a low side, and drives a gate of a power transistor. The gate drive device includes: a control device provided in pair to constitute the two sides, and configured to output a switching signal of three or more levels including a high level, a low level, and one or more intermediate levels between the high level and the low level according to a received control signal; and a switching element provided in pair corresponding to the control device, and configured to output, to the gate of the power transistor, a voltage corresponding to a level of the switching signal received from the control device.

A gate drive system according to an aspect of the invention operates on two sides, a high side and a low side, and drives a gate of a power transistor. The gate drive system includes: a controller configured to output a control signal that is changeable at three or more levels including a high level, a low level, and one or more intermediate levels; a control device provided in pair to constitute the two sides, and configured to output a switching signal corresponding to the control signal output from the controller; and a switching element provided in pair corresponding to the control device, and configured to output, to the gate of the power transistor, a voltage corresponding to a level of the switching signal received from the control device.

According to the gate drive device of the aspect of the invention, the control device can output the switching signal of three or more levels according to the received control signal. Then, the switching element that receives the switching signal outputs the voltage corresponding to the level of the switching signal to the gate of the power transistor. With such a configuration, a gate voltage of the power transistor can be dynamically controlled at a plurality of levels, and power saving of the power transistor can be achieved. Further, the gate drive device has a half-bridge configuration in which the control device and the switching element are each provided in pair, and the configuration is simplified, so that the gate drive device can be miniaturized.

According to the gate drive system of the aspect of the invention, the control device can output the switching signal corresponding to the control signal that is received from the controller and that is changeable at three or more levels. Then, the switching element that receives the switching signal outputs the voltage corresponding to the level of the switching signal to the gate of the power transistor. With such a configuration, a gate voltage of the power transistor is dynamically controlled, and thus power saving of the power transistor can be achieved. Further, the gate drive system has a half-bridge configuration in which the control device and the switching element are each provided in pair, and the configuration is simplified, so that the gate drive device can be miniaturized.

### BRIEF DESCRIPTION OF DRAWINGS

FIG. 1 is a diagram of a circuit using a gate driver according to an embodiment of the invention.

FIG. 2 is a detailed configuration diagram of an IC in the gate driver.

FIG. 3A is a detailed circuit configuration diagram of a DAC in the gate driver.

FIG. 3B is an equivalent circuit of the DAC.

FIG. 3C is an explanatory diagram of an output of the DAC.

FIG. 4 is a timing chart showing an operation example of active drive of the gate driver.

FIG. 5A is a timing chart showing an operation of single drive of the gate driver performed in a characteristic evaluation.

FIG. 5B is a graph showing a characteristic evaluation result of a gate voltage V_{GSH}.

FIG. 5C is a graph showing a characteristic evaluation result of a gate current I_{G}.

FIG. 6A is a circuit configuration diagram of a double pulse test of the gate driver.

FIG. 6B is a graph showing evaluation results of the single drive and the active drive in the double pulse test.

FIG. 7 is a circuit diagram showing a gate driver according to a first modification.

FIG. 8 is a circuit diagram showing a gate driver according to a second modification.

### DESCRIPTION OF EMBODIMENTS

Hereinafter, an embodiment of the invention will be described with reference to the drawings.

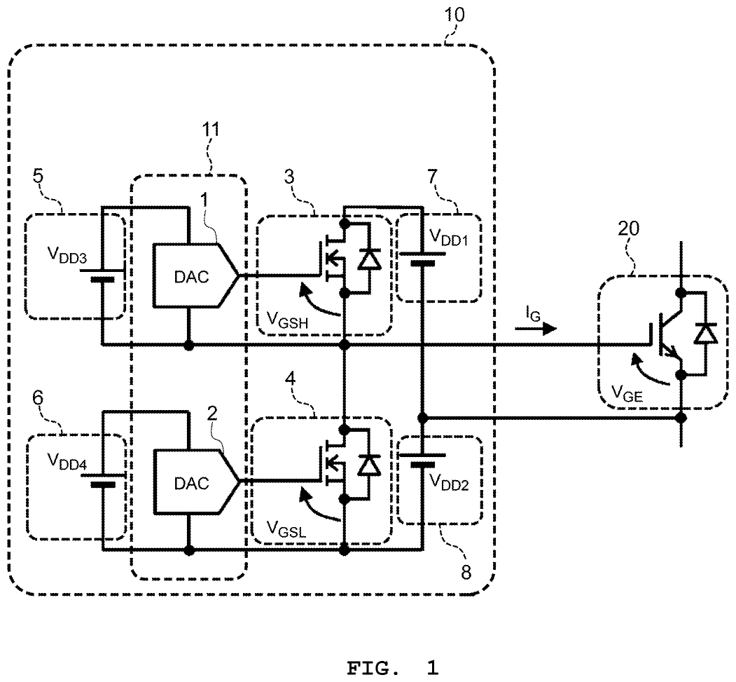

FIG. 1 is a diagram of a circuit using a gate driver according to an embodiment of the invention.

An output terminal of a gate driver 10 is connected to a gate and an emitter of a power transistor 20 in order to control the power transistor 20. The power transistor 20 is, for example, an insulated gate bipolar transistor (IGBT). Hereinafter, a potential of the gate with respect to the emitter in the power transistor 20 is referred to as a gate voltage V_{GE}, and a current input to the gate is referred to as a gate current I_{G}. The gate voltage V_{GE} of the power transistor 20 changes according to an output of the gate driver 10, and the power transistor 20 is controlled. The gate current I_{G} needs to exceed a predetermined value according to a standard of the power transistor 20.

The gate driver 10 has a half-bridge configuration, and has a configuration of two stages, an upper stage (high side) and a lower stage (low side) of the figure. In the gate driver 10 having the half-bridge configuration, while one of the high side and the low side is controlled, the other does not operate.

As described later, the gate driver 10 dynamically variably controls the gate voltage V_{GE} and the gate current I_{G} at a plurality of levels according to a digital control signal received from the outside. Such control of the gate can reduce a drive loss of the power transistor 20. The gate driver 10 is an example of a gate drive device, and a device capable of variably controlling a gate voltage may also be referred to as a digital gate driver. The dynamic variable control of the gate driver 10 at the plurality of levels is referred to as active control. The control of the gate driver 10 at one level (ON/OFF) is referred to as single-step control or single control.

The gate driver 10 includes a digital-to-analog converter (DAC) 1 and a metal-oxide-semiconductor field-effect transistor (MOSFET) 3 that constitute the high side, and a DAC 2 and a MOSFET 4 that constitute the low side. The two DACs 1 and 2, including a control circuit thereof, are integrated into an integrated circuit (IC) and implemented as an IC 11.

Hereinafter, a gate voltage with respect to a source of the high-side MOSFET 3 is referred to as V_{GSH}, and a gate voltage with respect to a source of the low-side MOSFET 4 is referred to as V_{GSL}. The gate voltages V_{GSH} and V_{GSL} of the MOSFETs 3 and 4 are controlled by the DACs 1 and 2, and the gate voltages V_{GSH} and V_{GSL} output from the DACs 1 and 2 are used for switching the MOSFETs 3 and 4, and therefore may be referred to as switching signals. A freewheeling diode is connected between a drain and the source of each of the MOSFETs 3 and 4, with a source side connected as an anode, that is, connected in anti-parallel to the MOSFETs 3 and 4.

On the high side, an output terminal of the DAC 1 is connected to a gate of the MOSFET 3. A DC voltage V_{DD3} is supplied from a power supply 5 to the DAC 1. One end of the DAC 1 connected to a negative electrode side of the power supply 5 is electrically connected to the source of the MOSFET 3. The DAC 1 transforms the supplied voltage V_{DD3} according to a control signal received from the outside, and outputs the transformed voltage to the gate of the MOSFET 3 at a desired level at a desired timing. By such control of the DAC 1, the gate voltage V_{GSH} is controlled, and the MOSFET 3 operates.

In the MOSFET 3, the source is connected to the gate of the power transistor 20, and the drain is connected to the emitter of the power transistor 20 via a power supply 7. The power supply 7 supplies a DC voltage V_{DD1}, and is provided such that the gate of the power transistor 20 has a high potential with respect to the emitter, that is, the gate voltage V_{GE} has a positive potential. In a high-side control zone, the MOSFET 3 is controlled according to the gate voltage V_{GSH}, and as a result, the gate voltage V_{GE} of the power transistor 20 is a positive voltage obtained by stepping down the voltage V_{DD1}.

A configuration of the low side is the same as that of the high side. An output terminal of the DAC 2 is connected to a gate of the MOSFET 4. A DC voltage V_{DD4} is supplied from a power supply 6 to the DAC 2. One end of the DAC 2 connected to a negative electrode side of the power supply 6 is electrically connected to the source of the MOSFET 4. The DAC 2 transforms the supplied voltage V_{DD4} according to a control signal received from the outside, and outputs the transformed voltage to the gate of the MOSFET 4 at a desired level at a desired timing. By such control of the DAC 2, the gate voltage Vest is controlled, and the MOSFET 4 operates.

In the MOSFET 4, the drain is connected to the gate of the power transistor 20, and the source is connected to the emitter of the power transistor 20 via a power supply 8. The power supply 8 supplies a DC voltage V_{DD2}, and is provided such that the emitter of the power transistor 20 has a high potential with respect to the gate, that is, the gate voltage V_{GE} has a negative potential. In a low-side control zone, the MOSFET 4 is controlled according to the gate voltage V_{GSL}, and as a result, the gate voltage V_{GE} of the power transistor 20 is a negative voltage obtained by stepping down the voltage V_{DD2}.

In this way, the gate voltages V_{GSH} and V_{GSL} of the MOSFETs 3 and 4 are controlled according to the control of the DACs 1 and 2. The gate voltage V_{GE} and the gate current I_{G} of the power transistor 20 are controlled according to changes in the gate voltages V_{GSH} and V_{GSL}. In the high-side control zone, the gate voltage V_{GE} of the power transistor 20 is the positive voltage corresponding to the gate voltage V_{GSH} of the MOSFET 3, and in the low-side control zone, the gate voltage V_{GE} of the power transistor 20 is the negative voltage corresponding to the gate voltage V_{GSL} of the MOSFET 4. The power transistor 20 is driven by such alternate control of the high side and the low side.

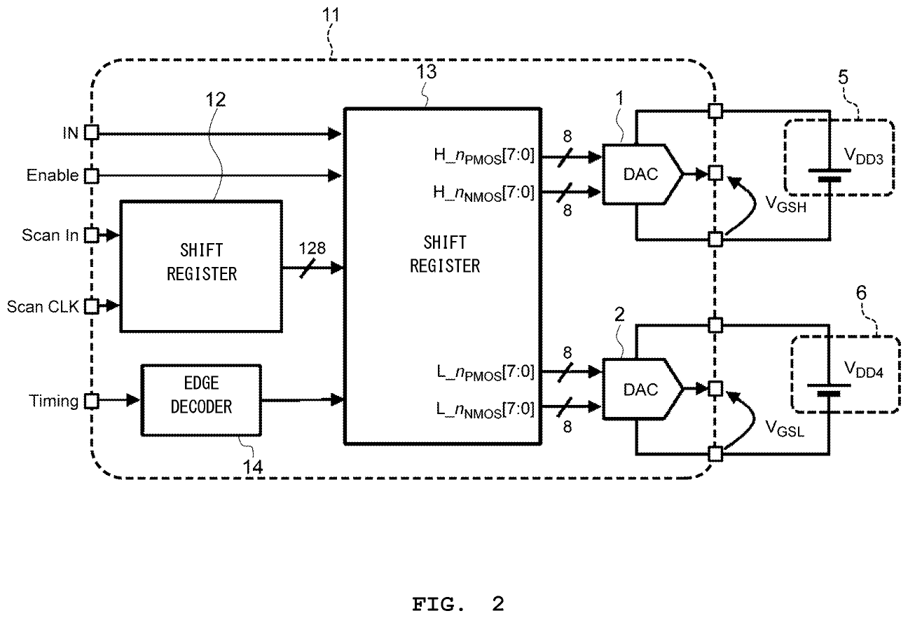

FIG. 2 is a detailed configuration diagram of the IC 11. The IC 11 is provided with the control circuit for the DACs 1 and 2. In this figure, the power supplies 5 and 6 are shown on a right side with respect to the DACs 1 and 2.

The IC 11 includes shift registers 12 and 13 and an edge decoder 14 which serve as the control circuit of the DACs 1 and 2. The control circuit including the shift registers 12 and 13 and the edge decoder 14 may be implemented by any type of controller. The shift register 12 receives an input of a serial signal and outputs a parallel signal. The shift register 13 receives an input of a parallel signal and outputs a serial signal.

The IC 11 receives an input signal (IN) and an enable signal (Enable) used for controlling the DACs 1 and 2, an input signal (Scan IN) and a clock signal (Scan CLK) used for scan design, and a timing signal (Timing) indicating a change timing of the outputs (gate voltages V_{GSH} and V_{GSL}) from the DACs 1 and 2. The scan design is implemented using the shift register 12 or the like, but a description of a detailed configuration of the scan design will be omitted.

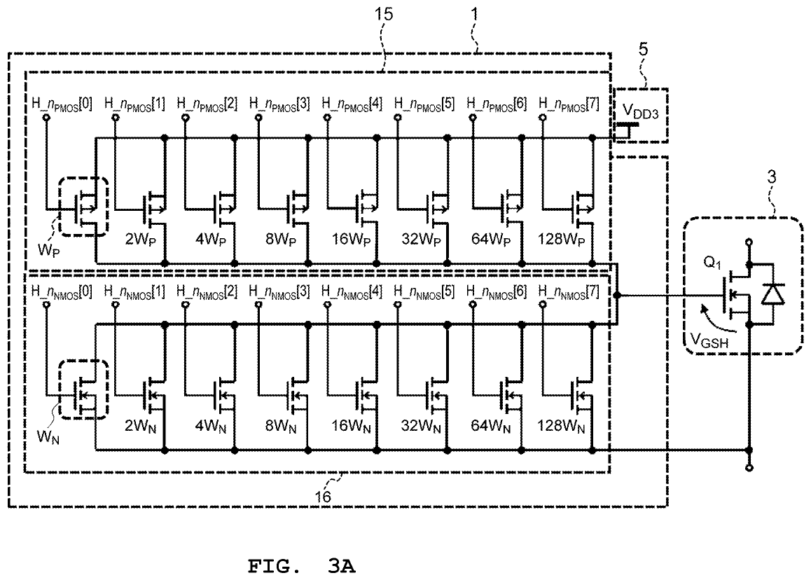

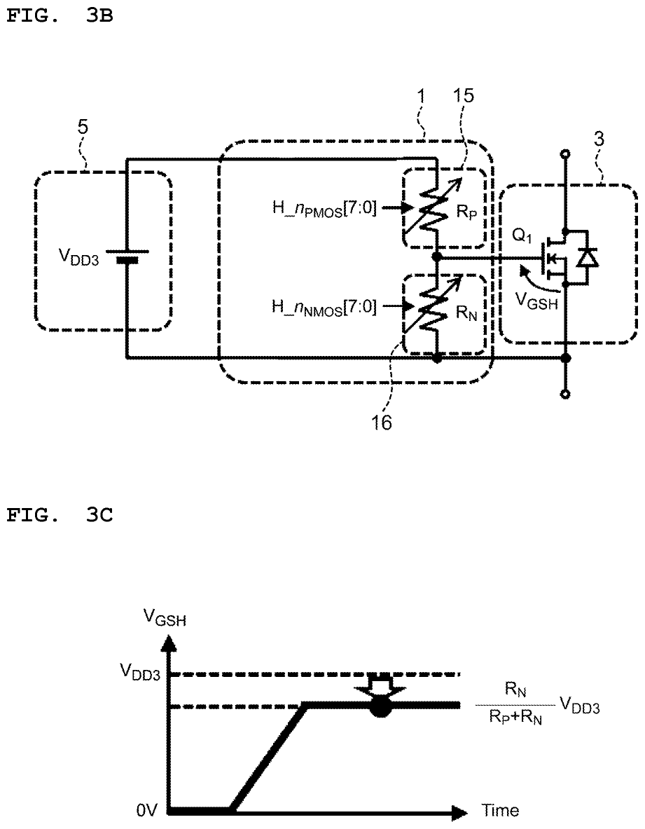

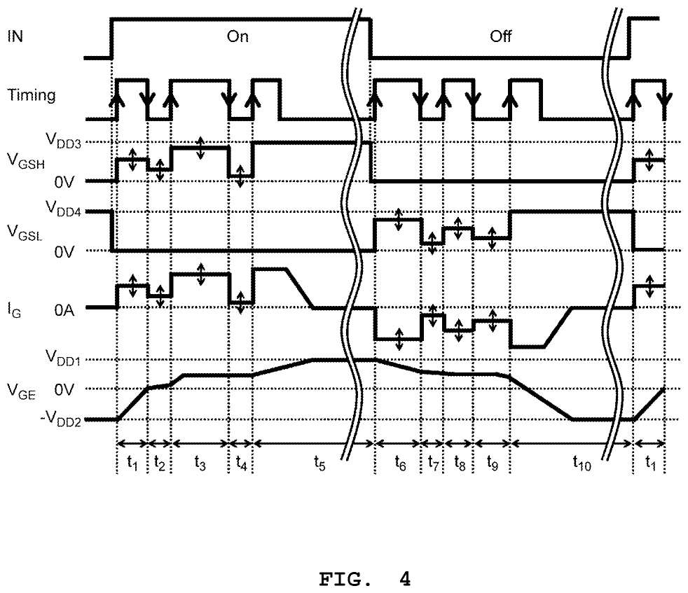

The shift register 13 receives the timing signal (Timing) from the edge decoder 14 in addition to the input signal (IN) and the enable signal (Enable). The shift register 13 outputs 8-bit control signals of H_n_{PMOS} and H_n_{NMOS} to the DAC 1, and outputs 8-bit control signals of L_n_{PMOS} and L_n_{NMOS} to the DAC 2. This output is updated at the change timing of the timing signal. In this way, the DACs 1 and 2 operate based on a digital control signal using the four 8-bit signals, and the gate voltages V_{GSH} and V_{GSL}, which are the switching signals for the MOSFETs 3 and 4, are output. Next, detailed configurations of the DACs 1 and 2 will be described with reference to FIGS. 3A to 3C.

FIG. 3A is a detailed circuit configuration diagram of the DAC 1. FIG. 3B is an equivalent circuit of the DAC 1. FIG. 3C is an explanatory diagram of the output of the DAC 1. As shown in FIGS. 3A and 3B, since the DAC 1 includes a variable resistance 15 on an upper part of the figure and a variable resistance 16 on a lower part of the figure, the output of the DAC 1 can be variably controlled as shown in FIG. 3C. Hereinafter, the configuration of the DAC 1 will be described in detail.

As shown in FIG. 3A, the variable resistance 15 is implemented by connecting switching elements W_{P}, 2W_{P}, 4W_{P}, 8W_{P}, 16W_{P}, 32W_{P}, 64W_{P}, and 128W_{P}, each having a resistance component, in parallel. In each of these switching elements W_{P}, one end is supplied with the voltage V_{DD3} from the power supply 5, and the other end is connected to the gate of MOSFET 3.

The number given at the head of the switching element W_{P} indicates a relative size of an area of the element. That is, the switching element 2W_{P} has a resistance value ½ times that of the switching element W_{P}. The switching elements W_{P}, 2W_{P}, 4W_{P}, 8W_{P}, 16W_{P}, 32W_{P}, 64W_{P}, and 128W_{P} are controlled by registers H_n_{PMOS}[0] to H_n_{PMOS}[7], respectively. As a result, a resistance value of the variable resistance 15 can be changed in 256 levels (0 to 255:8 bits).

Similarly, the variable resistance 16 is implemented by connecting switching elements W_{N}, 2W_{N}, 4W_{N}, 8W_{N}, 16W_{N}, 32W_{N}, 64W_{N}, and 128W_{N}, each having a resistance component, in parallel. In each of these switching elements W_{N}, one end is connected to the gate of the MOSFET 3, and the other end is connected to the source of the MOSFET 3. The switching elements W_{N}, 2W_{N}, 4W_{N}, 8W_{N}, 16W_{N}, 32W_{N}, 64W_{N}, and 128W_{N} are controlled by registers H_n_{NMOS} [0] to H_n_{NMOS} [7], respectively. As a result, a resistance value of the variable resistance 16 can be changed in 256 levels (0 to 255:8 bits).

As shown in FIG. 3B, the DAC 1 is equivalent to a configuration in which the variable resistance 15 whose resistance value changes by being controlled by the registers H_n_{PMOS}[0] to H_n_{PMOS}[7] and the variable resistance 16 whose resistance value changes by being controlled by the registers H_n_{NMOS}[0] to H_n_{NMOS}[7] are connected in series. The voltage V_{DD3} is supplied from the power supply 5 to the variable resistances 15 and 16. A connection point between the variable resistance 15 and the variable resistance 16 is connected to the gate of the MOSFET 3, and terminals of the variable resistances 15 and 16 connected to the negative electrode side of the power supply 5 are connected to the source of the MOSFET 3.

FIG. 3C shows the gate voltage V_{GSH} of the MOSFET 3 controlled by the DAC 1. The gate voltage V_{GSH} is determined by stepping down the voltage V_{DD3} of the power supply 5 according to the resistance values of the variable resistances 15 and 16. Specifically, when the resistance value of the variable resistance 15 is R_{P} and the resistance value of the variable resistance 16 is R_{N}, the gate voltage V_{GSH} is a value obtained by multiplying V_{DD3} by (R_{N}/(R_{P}+R_{N}).

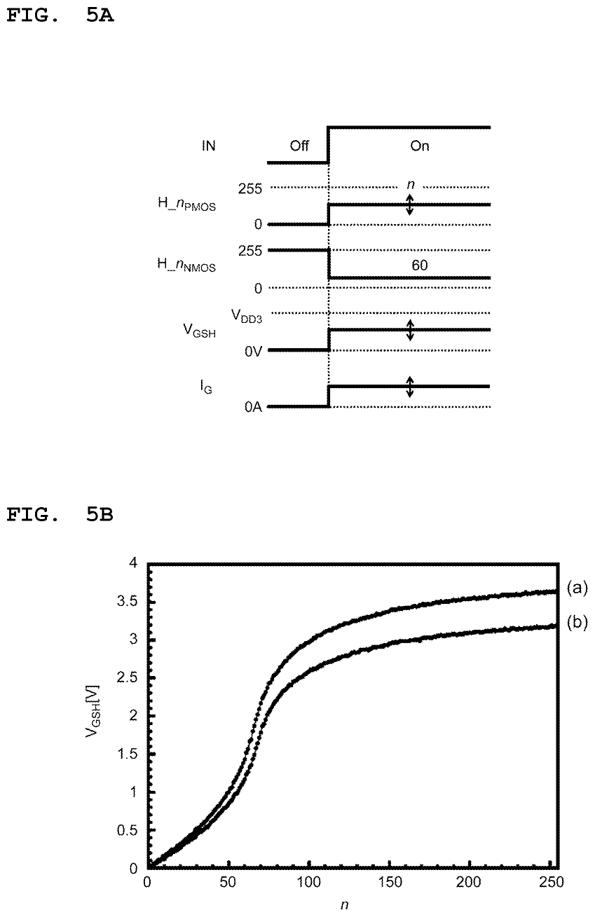

FIG. 4 is a timing chart showing an operation example of active drive of the gate driver 10. One cycle is constituted by combining a case where the IN signal input to the gate driver 10 is ON (high side) and a case where the IN signal is OFF (low side).

In periods t₁ to t₅ in which the IN signal is ON, the gate voltage V_{GSH} of the high-side MOSFET 3 is variably controlled at a plurality of levels, and the gate voltage V_{GSL} of the low-side MOSFET 4 becomes zero. At a change timing of the timing signal, the gate voltage V_{GSH} of the MOSFET 3 is controlled according to H_n_{PMOS}[0] to H_n_{PMOS}[7], and the gate current I_{G} and the gate voltage V_{GE} of the power transistor 20 are controlled.

Specifically, the gate voltage V_{GSH} is set to a plurality of levels between 0 V to V_{DD3} in the periods t₁ to t₄, and becomes V_{DD3} in the final period t₅. On the other hand, in the periods t₁ to t₅, the gate voltage V_{GSL} remains zero. As the gate voltage V_{GSH} changes, the gate current I_{G} increases or decreases in a positive range and finally becomes zero. At the same time, the gate voltage V_{GE} gradually increases and finally becomes the predetermined value V_{DD1}.

On the other hand, in periods t₆ to t₁₀ in which the IN signal is OFF, the gate voltage V_{GSL} of the low-side MOSFET 4 is variably controlled at a plurality of levels, and the high-side gate voltage V_{GSH} becomes zero. Similarly, since a voltage level of the gate voltage V_{GSL} changes according to the input of the timing signal, the gate current I_{G} of the IGBT 2 can be controlled in a negative region, and the gate voltage V_{GE} can be controlled in a decreasing region.

In this example, the gate voltage V_{GSL} of the low-side MOSFET 4 is set to a plurality of levels between 0 V to V_{DD4} in the periods t₆ to t₉, and becomes V_{DD4} in the final period t₁₀. On the other hand, in the periods t₆ to t₁₀, the gate voltage V_{GSH} remains zero. As the gate voltage V_{GSL} changes, the gate current I_{G} increases or decreases in a negative range and finally becomes zero. At the same time, the gate voltage V_{GE} gradually decreases and finally becomes −V_{DD2}.

By repeating such control in t₁ to t₁₀, the gate driver 10 can control the gate current I_{G} and the gate voltage V_{GE} of the power transistor 20.

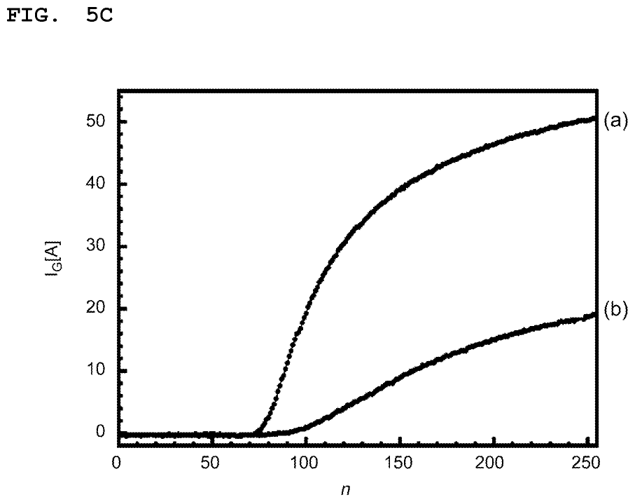

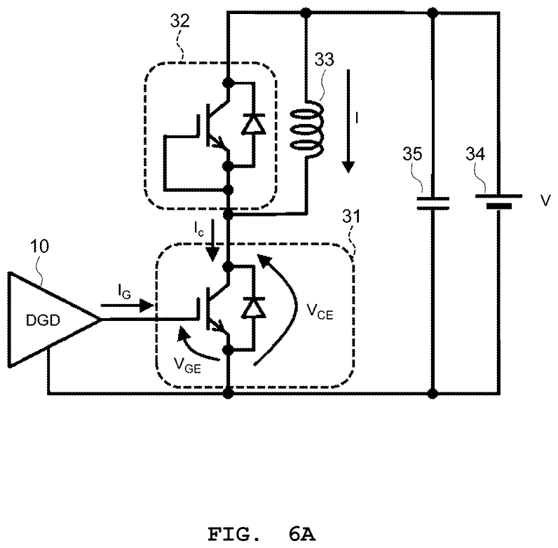

Next, a characteristic evaluation performed on the gate driver 10 will be described with reference to FIGS. 5A to 5C. In this characteristic evaluation, the single-step control, which is single control to a predetermined level, was performed instead of the active control shown in FIG. 4.

FIG. 5A is a timing chart showing an operation of the single-step control of the gate driver 10 in the characteristic evaluation. FIG. 5B is a graph showing a characteristic of the gate voltage V_{GSH}. FIG. 5C is a graph showing a characteristic of the gate current I_{G}. This characteristic evaluation was performed in an environment in which a 100 μF film capacitor was connected to the gate driver 10, and evaluation results shown in FIGS. 5B and 5C were obtained by performing the single-step control shown in FIG. 5A.

As shown in FIG. 5A, when the IN signal is switched from OFF to ON, H_n_{PMOS} was changed from 0 to n (predetermined value from 0 to 255), and H_n_{NMOS} was changed from 255 to 60. When H_n_{PMOS} and H_n_{NMOS} change, the gate voltage V_{GSH} of the MOSFET 3 and the gate current I_{G} of the power transistor 20 change. By changing n in such control from 0 to 255, the characteristics of the gate voltage V_{GSH} and the gate current I_{G} as shown in FIGS. 5B and 5C were obtained.

FIGS. 5B and 5C each show measurement results under two conditions, (a) and (b). In (a), respective characteristic results of the gate voltage V_{GSH} and the gate current I_{G} are shown according to a change in n when V_{DD1} and V_{DD2} are 15 V and V_{DD3} and V_{DD4} are 4 V. In (b), respective characteristic results of the gate voltage V_{GSH} and the gate current I_{G} are shown according to a change in n when V_{DD1} is 15 V, V_{DD2} is 0 V, and V_{DD3} and V_{DD4} are 3.5 V.

FIG. 5B shows a substantially linear correlation in which the gate voltage V_{GSH} increases by increasing n stepwise. FIG. 5C shows a correlation in which the gate current I_{G} gradually increases from n=70 to 100 as n is increased stepwise. As shown in (a) of FIG. 5C, the gate current I_{G} increases to about 51 A. In general, in control of a large-capacity power transistor, the gate current I_{G} is required to be 40 A or more, but the gate driver 10 of the present embodiment exceeds the required level. From such evaluation results, it can be understood that the gate driver 10 of the present embodiment has a linear characteristic in the gate voltage V_{GSH} and has a large capacitance in the gate current I_{G}.

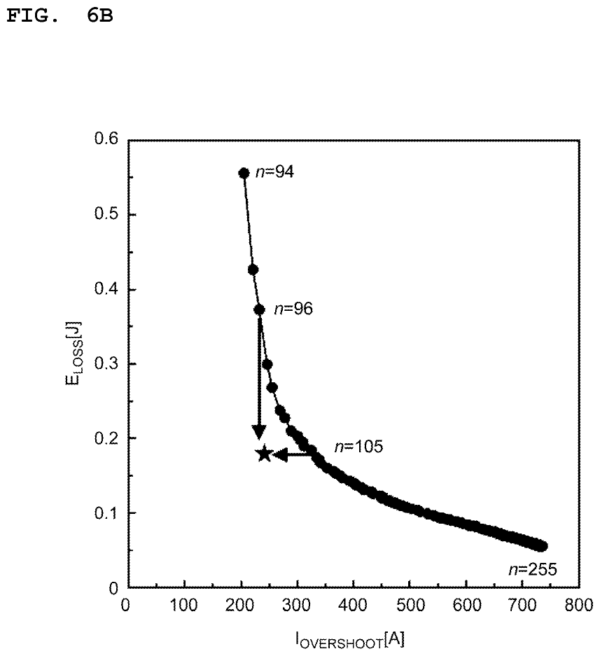

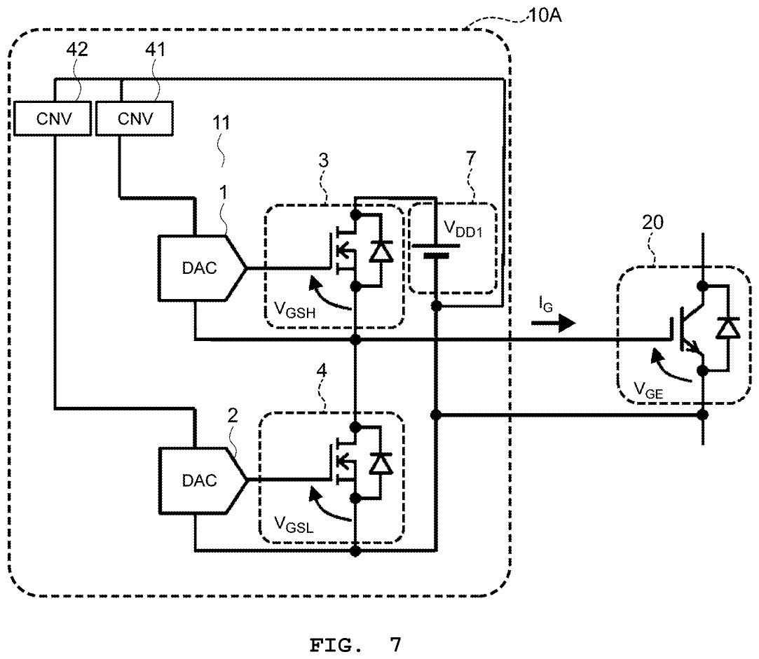

Next, evaluation results of a drive performance of the gate driver 10 (digital gate driver (DGD)) obtained by a double pulse test will be described with reference to FIGS. 6A and 6B. FIG. 6A is a circuit configuration diagram of an evaluation environment of the double pulse test. FIG. 6B is a graph showing the drive performance of the gate driver 10 in the double pulse test.

FIG. 6A shows the circuit configuration diagram of the double pulse test of 600 V/200 A. In this circuit, two power transistors 31 and 32 are connected in series. A gate of the power transistor 31 on a lower part of the figure receives an input from the gate driver 10. An inductance 33 is connected in parallel to the power transistor 32 on an upper part of the figure. In this test environment, the power transistors 31 and 32 in which a maximum value of a voltage between a collector and an emitter was 6500 V and a maximum value of a collector current was 1000 A were used. In the gate driver 10, V_{DD1} is 15 V, V_{DD2} is 0 V, and V_{DD3} and V_{DD4} are 3.5 V.

A power supply 34 is connected to both ends of the power transistors 31 and 32 connected in series, and a capacitor 35 is provided in parallel with the power supply 34. A voltage of 600 V is supplied by the power supply 34, and a current of 200 A flows through the inductance 33. In such an environment, the double pulse test was performed by controlling the power transistor 31 using the gate driver 10.

FIG. 6B is a diagram showing results of the double pulse test using the environment of FIG. 6A. In this figure, as the results of the double pulse test, an overshoot current (I_{OVERSHOOT}) of the power transistor 31 is shown on an X-axis (horizontal axis), and a power loss (E_{LOSS}) of the power transistor 31 is shown on a Y-axis (vertical axis).

Circles indicate a correlation between the overshoot current and the power loss when n is changed from 94 to 255 in a case where the gate driver 10 is controlled by the single-step control shown in FIG. 5A. According to this figure, it can be understood that there is a tread-off relationship in which the overshoot current decreases as n decreases and the power loss decreases as n increases.

A star indicates a result when the gate driver 10 is actively controlled. In the active control, as shown in FIG. 4, the gate voltages V_{GSH} and V_{GSL} of the MOSFET 3 are controlled to pass through an intermediate level during transition from OFF (low level) to ON (high level). The evaluation result shown in FIG. 6B is obtained by the active control with a pattern different from that of FIG. 4.

When the result of the star is compared with that of the circle of n=96, the power loss can be reduced by 51% from 0.37 J to 0.18 J with almost the same overshoot current. When the result of the star is compared with that of the circle of n=105, the overshoot current can be reduced by 26% from 326 A to 242 A with almost the same power loss. In this way, it can be understood that the power transistors 31 and 32 can be driven with higher efficiency by variably controlling the gate driver 10 of the present embodiment.

In the description of the present embodiment, the MOSFETs 3 and 4 are used as switches controlled by the DACs 1 and 2, but the invention is not limited thereto. A bipolar transistor may be used instead of the MOSFET. While the MOSFET is controlled according to the gate voltage, the bipolar transistor is controlled by the gate current. Therefore, the gate voltage of the power transistor 20 connected to the bipolar transistor can be variably and dynamically controlled by controlling the current output from the DACs 1 and 2 at three or more levels including an intermediate level.

The DACs 1 and 2, which are digital-to-analog converters, are used as control devices for controlling the switching elements, but the invention is not limited thereto. A device capable of outputting a signal of three or more levels including a high level, a low level, and one or more intermediate levels between the high level and the low level according to a received control signal may be alternatively used.

Further, by changing the MOSFETs 3 and 4 to MOSFETs having different rated currents, a maximum value of an output current, that is, the gate current I_{G} of the power transistor 20 output from the gate driver 10 can be changed. By changing the voltages V_{DD3} and V_{DD4} of the power supplies 5 and 6 that supply power to the DACs 1 and 2 to power supplies having different voltages, the maximum value of the gate current I_{G} output from the gate driver 10 can be changed. Since the MOSFETs 3 and 4 and the power supplies 5 and 6 are modularized and easily replaced, a performance of the gate driver 10 can be changed by changing these components.

In this way, the gate driver 10 of the present embodiment includes the two DACs 1 and 2 and the MOSFETs 3 and 4. The outputs from the DACs 1 and 2 are variably and dynamically controlled at three or more levels including a high level, a low level, and one or more intermediate levels between the high level and the low level according to a digital control signal received from the shift register 13. The MOSFETs 3 and 4 can dynamically control (actively control) the gate voltage V_{GE} and the gate current I_{G} of the power transistor 20 to be controlled, at a plurality of levels according to the levels of the outputs from the DACs 1 and 2. As a result, as shown in FIG. 6B, both the overshoot current and the power loss of the power transistor 20 can be reduced.

Further, the control circuit of the DACs 1 and 2 is implemented by the IC 11 including the shift register 13. The IC 11 is provided with one control circuit (shift registers 12 and 13 and edge decoder 14) that outputs a control signal to the two DACs 1 and 2. In this way, the two DACs 1 and 2 are controlled by using one control circuit, so that the IC 11 can be miniaturized. The gate driver 10 has the half-bridge configuration including two sides, the high side and the low side, and thus can be operated in both turn-on control and turn-off control.

According to the present embodiment, the outputs of the DACs 1 and 2 are the gate voltages V_{GSH} and V_{GSL} of the MOSFETs 3 and 4, and with such a configuration, switching control of the MOSFETs 3 and 4 can be performed directly. The switching control of the MOSFETs 3 and 4 can also be performed indirectly by changing gate voltages to grounds of the MOSFETs 3 and 4 instead of directly controlling the gate voltages V_{GSH} and V_{GSL} as in the present embodiment. On the other hand, in the present embodiment, a control accuracy of the MOSFETs 3 and 4 can be improved by changing the gate voltages directly rather than indirectly.

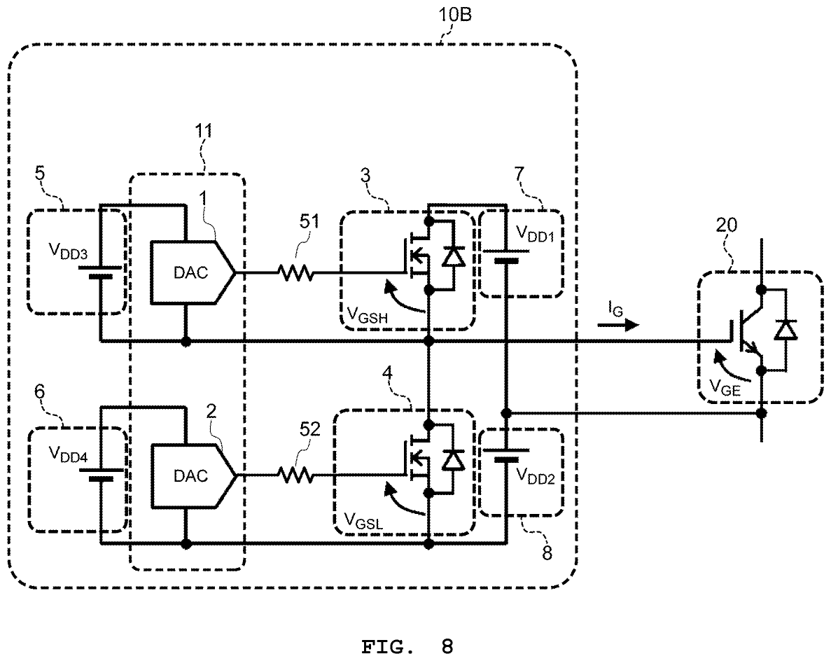

Next, another modification of the gate driver 10 will be described with reference to FIGS. 7 and 8.

FIG. 7 is a diagram showing a gate driver 10A according to a first modification. In the gate driver 10A shown in this figure, the power supply 5 that supplies a voltage to the DAC 1, the power supply 6 that supplies a voltage to the DAC 2, and the power supply 8 that constitutes low-side output power are omitted as compared with the gate driver 10 of the first embodiment shown in FIG. 1. At the same time, the DACs 1 and 2 are supplied with a predetermined voltage from the power supply 7 by changing voltage converters 41 and 42, instead of the power supplies 5 and 6.

With such a configuration, the DACs 1 and 2 can be driven by transforming and supplying the voltage of the power supply 7 (second power supply) without providing the power supplies 5 and 6 (first power supply). Further, the gate driver 10A can be implemented even if one power supply 7 (second power supply) is provided for the two MOSFETs 3 and 4. According to such a configuration, the number of power supplies in the gate driver 10A can be reduced, and a configuration can be simplified.

FIG. 8 is a diagram showing a gate driver 10B according to a second modification. In the gate driver 10B shown in this figure, a resistance 51 is provided between the DAC 1 and the MOSFET 3, and a resistance 52 is provided between the DAC 2 and the MOSFET 4, as compared with the gate driver 10 of the first embodiment shown in FIG. 1. With this configuration, the outputs from the DACs 1 and 2 can be smoothed, and as a result, an operation of the power transistor 20 operated by the gate driver 10B can be stabilized.

As shown in the first modification, the number of power supplies of the gate driver 10A can be reduced, and as shown in the second modification, the operation of the gate driver 10B can be stabilized by providing the resistances 51 and 52. In addition to the configurations shown in these modifications, the gate driver 10 can take various modifications.

Various embodiments and modifications may be made without departing from the broad spirit and scope of the invention. The above-described embodiment is for describing the invention, and does not limit the scope of the invention. That is, the scope of the invention is indicated by the claims rather than the embodiment. Various modifications made within the scope of the claims and the meaning of the invention equivalent thereto are regarded as within the scope of the invention.

1. A gate drive device that operates on two sides, a high side and a low side, and drives a gate of a power transistor, the gate drive device comprising:
a control device provided in pair to constitute the two sides, and configured to output a switching signal of three or more levels including a high level, a low level, and one or more intermediate levels between the high level and the low level according to a received control signal; and
a switching element provided in pair corresponding to the control device, and configured to output, to the gate of the power transistor, a voltage corresponding to a level of the switching signal received from the control device.

2. The gate drive device according to claim 1, wherein
the switching element is a MOSFET, and
the control device is configured to output the switching signal corresponding to the received control signal to a gate of the switching element.

3. The gate drive device according to claim 1, wherein
the switching element is a MOSFET, and
the control device is configured to change a gate voltage of the switching element at three or more levels according to the received control signal.

4. The gate drive device according to claim 1, wherein
the switching element is a bipolar transistor, and
the control device is configured to change a gate current of the switching element at three or more levels according to the received control signal.

5. The gate drive device according to claim 1, wherein
the control device is a digital-to-analog converter configured to convert a received voltage based on the control signal that is a received digital signal, and output the converted voltage as the switching signal.

6. The gate drive device according to claim 1, wherein
in an operation on at least one of the two sides, the control signal is at the intermediate level in at least one of a period during which the control signal changes from the high level to the low level and a period during which the control signal changes from the low level to the high level.

7. The gate drive device according to claim 1, wherein
a maximum current that is allowed to be output from the switching element to the gate of the power transistor is determined according to a rated current of the switching element.

8. The gate drive device according to claim 1, wherein
a maximum current that is allowed to be output from the switching element to the gate of the power transistor is determined according to a voltage supplied to the control device.

9. The gate drive device according to claim 1, wherein
for the control device provided in pair, one controller configured to generate the control signal for the control device is provided.

10. The gate drive device according to claim 1, wherein
the control device is configured to receive power supplied from a first power supply and output the switching signal, and
the switching element is configured to convert a voltage received from a second power supply according to the switching signal, and output a voltage corresponding to a level of the switching signal obtained by the conversion to the gate of the power transistor.

11. The gate drive device according to claim 10, wherein
the first power supply is formed by transforming the second power supply.

12. The gate drive device according to claim 10, wherein at least one of a pair of the switching elements is provided with the second power supply.

13. The gate drive device according to claim 1, further comprising:
a resistance provided between the control device and the switching element.

14. A gate drive system that operates on two sides, a high side and a low side, and drives a gate of a power transistor, the gate drive system comprising:
a controller configured to output a control signal that is changeable at three or more levels including a high level, a low level, and one or more intermediate levels;
a control device provided in pair to constitute the two sides, and configured to output a switching signal corresponding to the control signal output from the controller; and
a switching element provided in pair corresponding to the control device, and configured to output, to the gate of the power transistor, a voltage corresponding to a level of the switching signal received from the control device.
